(19) United States
(12) Patent Application Publication
(10) Pub. No.: US 2003/0232286 A1
(43) Pub. Date: Dec. 18, 2003

(54) Method for forming metal colloid patterns

(75) Inventors: Emi Watanabe, Osaka-city (JP); Takeshi Oka, Kobe-city (JP); Ayako Iwakoshi, Toyonaka-city (JP)

Correspondence Address: Law Offices of Townsend & Banta, Suite 500, 1225 Eye Street, N.W., Washington, DC, 20005, US

(73) Assignee: Nippon Paint Co., Ltd.

(21) Appl. No.: 10/462,641

(22) Filed: Jun. 17, 2003

(30) Foreign Application Priority Data
Jun. 18, 2002 (JP) 176644/2002

(51) Int. Cl. G03F 7/16; G03F 7/20; G03F 7/40

(52) U.S. Cl. 430/315; 430/320; 430/319; 430/324

(57) ABSTRACT

The metal colloid pattern formation method is a method for forming metal colloid patterns on a substrate by forming a photosensitive layer on a substrate by applying a photosensitive resin composition containing an organic solvent and a polysilane soluble in the organic solvent to the substrate, forming a latent image of the patterns by selectively exposing the photosensitive layer, bringing a metal colloid-containing solution into contact with the photosensitive layer, and forming patterns of the metal colloid by adsorbing the metal colloid in the exposed parts.

### BACKGROUND OF THE INVENTION

1. Field of the Invention

The invention relates to a method for forming metal colloid patterns using a polysilane, particularly relates to a method for forming metal colloid patterns for coloring materials, optical filters, film catalysts, and other uses.

2. Related Art

As a method for patterning a thin film of a metal colloid has conventionally been known a method involving steps of forming a thin film of a metal colloid on a substrate, forming a photoresist film having prescribed patterns thereon, and removing the metal colloid thin film by etching. Also, methods involving steps of forming a thin film of a polysilane on a substrate, forming a latent image of patterns by selectively exposing the film, and after that, vacuum depositing gold and heating, and finally removing the deposited film in the unexposed parts are reported (Adv. Mater., 9, 71(1997), Chem. Lett., 397(1997), Mol. crystal. Liq. Cryst., 316, 411(1998)) as a method for patterning a metal colloid thin film using a polysilane. Further, a method involving steps of UV exposing a polymetal compound such as a polysilane to cut metal bonds and then bringing the resulting polymetal compound into contact with a metal salt solution to reduce the metal salt in the unexposed parts and form a metal thin film only on the unexposed parts is proposed (Japanese Patent Publication Laid-Open No. S57-11339).

Meanwhile, methods for forming colored patterns by pattern-wise exposing a polysilane thin film formed on a substrate and then dipping the resulting substrate in a dye solution or a pigment dispersion containing silica sol have been proposed so far (Japanese Patent Publication Laid-Open Nos. H5-47782 and H8-262727).

However, the above-mentioned conventional methods for forming metal colloid patterns include vacuum process and involve complicated steps and thus have disadvantages that formation of the metal colloid patterns are not easy.

Also, with respect to the above-mentioned colored pattern formation methods, there are problems that discoloration takes place in the case of storage at a high temperature attributed to low heat resistance of dyes and pigments.

### SUMMARY OF THE INVENTION

The aim of the invention is to provide a method for forming metal colloid patterns by which colored patterns excellent in heat resistance can be easily formed.

A metal colloid pattern formation method of the invention is a method for forming metal colloid patterns on a substrate. This method involves steps of forming a photosensitive layer on a substrate by applying a photosensitive resin composition containing an organic solvent and a polysilane soluble in the organic solvent to the substrate, forming a latent image of the patterns by selectively exposing the photosensitive layer, bringing a metal colloid solution into contact with the photosensitive layer, and forming patterns of the metal colloid by adsorbing the metal colloid in the exposed parts.

In the invention, the photosensitive layer containing a polysilane is selectively exposed and the latent image of patterns is formed and after that, a metal colloid-containing solution is brought into contact with the photosensitive layer and the metal colloid is adsorbed in the exposed parts of the photosensitive layer. Accordingly, the metal colloid patterns formed by the invention have high adhesion strength and are hardly peeled off.

Further, the photosensitive resin composition for forming the photosensitive layer in the invention may additionally contain an oxidizing agent, a photoradical generating agent, or a silicone compound.

The metal colloid-containing solution to be employed in the invention is not particularly limited if it contains a metal colloid, however a solution containing metal colloid particles with an average particle diameter of about 5 nm to 100 nm is preferable. As such a metal colloid-containing solution, those containing a metal colloid and a polymer pigment dispersant can be exemplified and for example, metal colloid-containing solutions disclosed in Japanese Patent Publication Laid-Open No. H11-80647 can be exemplified.

### BRIEF DESCRIPTION OF THE DRAWING

FIGS. 1A to 1C are schematical cross-sectional views showing one example of the production process of a metal colloid pattern formation method of the invention.

### DESCRIPTION OF THE PREFERRED EMBODIMENTS

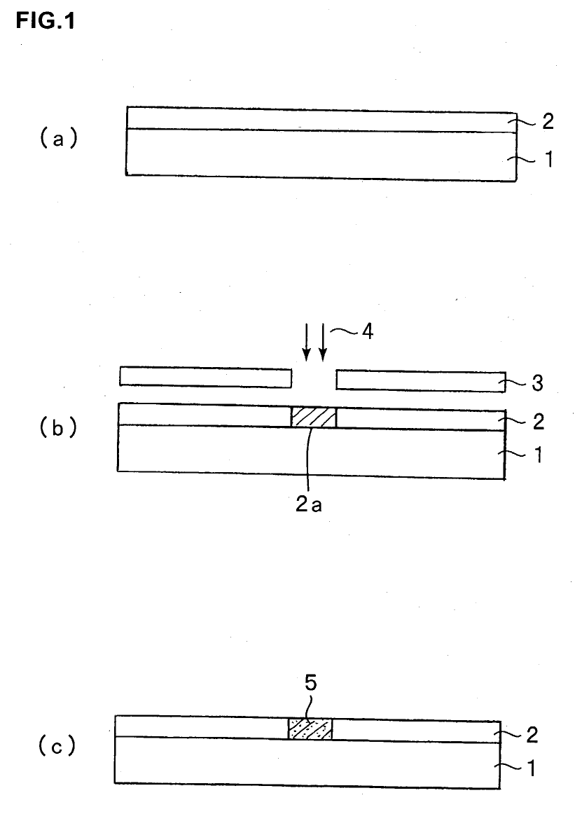

FIGS. 1A to 1C are schematical cross-sectional views for illustrating a metal colloid pattern formation method of the invention.

As shown in FIG. 1A, at first, a photosensitive layer 2 is formed on a substrate 1 by coating a photosensitive resin composition thereto.

Next, as shown in FIG. 1B, a mask 3 is put on the photosensitive layer 2 and UV rays 4 are exposed to the photosensitive layer 2 through the mask 3. The mask 3 is patterned so as to expose the area to form the metal colloid patterns. Accordingly, the regions corresponding to the metal colloid patterns to be formed are exposed in the photosensitive layer 2 to form the latent image parts 2a. In this case, although the photosensitive layer is exposed using a mask, the invention is not limited to this method, but exposure may be carried out without using a mask in the case of entire surface exposure. Also, laser beam scanning may be carried out to expose selectively.

In the latent image parts 2a, the polysilane is radiated with UV rays in the presence of oxygen to cut Si—Si bonds and form Si—OH groups (silanol groups). Accordingly, in the latent image parts 2a, the resin is changed to be polar from non-polar and made to be hydrophilic.

Next, as shown in FIG. 1C, the photosensitive layer 2 is brought into contact with a metal colloid-containing solution to adsorb the metal colloid in the latent image parts 2a. In the regions other than the latent image parts 2a is adsorbed no metal colloid and the metal colloid can be easily removed by washing. Accordingly, the metal colloid is adsorbed only in the latent image parts 2a and the metal colloid patterns 5 can be formed in the photosensitive layer 2.

Hereinafter, the photosensitive resin composition and the metal colloid-containing solution to be used for the invention will be described.

<Photosensitive Resin Composition>

A photosensitive resin composition to be used in the invention contains an organic solvent, a polysilane soluble in the organic solvent, and further based on the necessity, an oxidizing agent, a photoradical generating agent, and a silicone compound. Hereinafter, these compounds will be described.

(Polysilane)

As a polysilane to be used in the invention, network type or straight chain polysilanes can be exemplified. In consideration of the mechanical strength as a photosensitive material, the network type polysilanes are preferable. The network type ones and the straight chain type ones can be distinguished based on the bonding state of Si atoms contained in the polysilanes. A network type polysilane is a polysilane containing Si atoms having 3 or 4 bonds (bond number) in number with neighboring Si atoms. On the other hand, a straight chain type polysilane contains Si atoms having 2 bonds with neighboring Si atoms. Since the atomic valence of Si atom is 4 in general, Si atoms with a bond number of 3 or less among Si atoms existing in a polysilane are bonded with hydrocarbon groups, alkoxy groups, hydroxy groups, or hydrogen atoms other than neighboring Si atoms. Such hydrocarbon groups are preferably, for example, aliphatic hydrocarbon groups with 1 to 10 carbons which may be substituted with halogen or hydroxy groups and aromatic hydrocarbon groups with 6 to 14 carbons.

Practical examples of the aliphatic hydrocarbon groups include chain groups such as methyl, propyl, butyl, hexyl, octyl, decyl, trifluoropropyl, and nonafluorohexyl and alicyclic groups such as cyclohexyl, methylcyclohexyl and the like.

Practical examples of the aromatic hydrocarbon groups include phenyl, p-tolyl, biphenyl, anthracyl and the like. As alkoxy groups, those with 1 to 8 carbons can be exemplified. Practical examples include methoxy, ethoxy, phenoxy, octyloxy and the like. In consideration of easiness of synthesis, methyl and phenyl are especially preferable among them.

In the case of a network type polysilane, it is preferable that the ratio of Si atoms which have 3 or 4 bonds with neighboring Si atoms is 2 to 50% in the entire Si atoms in the network type polysilane. The ratio can be determined by nuclear magnetic resonance spectrometry of Si.

Incidentally, the polysilane in this specification also includes a mixture of a network type and a straight chain polysilanes. In such a case, the content of the above-mentioned Si atoms can be calculated based on the average of the network type polysilane and the straight chain type polysilane.

The polysilane to be used for the invention can be produced by condensation polymerization reaction heated higher than 80° C. of a halogenated silane compound in an organic solvent such as n-decane and toluene in the presence of an alkali metal such as sodium.

The network type polysilane can be obtained by, for example, heating a halosilane mixture containing an organotrihalosilane compound, a tetrahalosilane compound, and a diorganodihalosilane compound in a ratio of not less than 2% by mole and less than 50% by mole in total of the organotrihalosilane and tetrahalosilane compounds to cause condensation polymerization. In this case, the organotrihalosilane compound becomes a source of Si atoms having 3 bonds with neighboring Si atoms and the tetrahalosilane compound becomes a source of Si atoms having 4 bonds with neighboring Si atoms. Incidentally, the network structure can be confirmed by UV absorption spectrometry and nuclear magnetic resonance spectrometry of Si.

Compounds generally so-called polysilyne may be used as the network type polysilane. As the polysilyne may be used a network type polysilane exemplified in Japanese Patent Publication Laid-Open No. 2001-48987. That is, a network type polysilane produced by making Mg or a Mg alloy react on a trihalosilane in coexistence of a Li salt and a metal halide in a non-protonic solvent.

The straight chain polysilane can be produced by similar reaction to that of the above-mentioned network type polysilane except that a plurality or a single diorganodichlorosilane is used.

The halogen atoms contained in the organotrihalosilane compounds, tetrahalosilane compounds, and diorganodihalosilane compounds to be used as raw materials of the polysilane are preferably chlorine atoms. The substituents of the organotrihalosilane compounds and diorganodihalosilane compounds other than halogen atoms may include the above-mentioned hydrocarbon groups, alkoxy groups or hydrogen atoms.

These network type and straight chain type polysilanes are soluble in an organic solvent and are not particularly limited. In consideration of use for photosensitive materials, the polysilanes to be used in the invention are preferably soluble in a volatile organic solvent. Such an organic solvent includes solvents of hydrocarbon type with 5 to 12 carbons, halogenated hydrocarbon type, and ether type.

Examples of the hydrocarbon type solvent are pentane, hexane, heptane, cyclohexane, n-decane, n-dodecane, benzene, toluene, xylene, methoxybenzene, and the like. Examples of the halogenated hydrocarbon type are tetrachloromethane, chloroform, 1,2-dichloroethane, dichloromethane, chlorobenzene and the like. Examples of the ether type are diethyl ether, dibutyl ether, tetrahydrofuran and the like.

As the polysilanes to be used in the invention, those with a weight average molecular weight of 3,000 or high are preferable. If the weight average molecular weight is less than 3,000, the film properties such as chemical resistance and heat resistance may become insufficient in some cases. The weight average molecular weight is more preferably 5,000 to 50,000 and furthermore preferably 5,000 to 20,000.

(Organic Solvent)

The organic solvent to be contained in the photosensitive resin composition of the invention is not particularly limited if it can dissolve polysilanes therein and practical examples are the organic solvents exemplified in the description of the polysilanes.

(Oxidizing Agent)

The oxidizing agent to be used in the invention is not particularly limited if it is a compound to be an oxygen supply source and for example, peroxides, amine oxides, and phosphine oxides can be exemplified.

The oxidizing agent is added to easily insert oxygen into Si bonds after cutting the bonds.

(Photoradical Generating Agent)

The photoradical generating agent to be employed in the invention is not limited if it is a compound capable of generating halogen radical by light and may include 2,4,6-tris(trihalomethyl)-1,3,5-triazine and its derivatives having substituent(s) at the 2nd position or the 2nd and 4th positions, phthalimide trihalomethanesulfonate and its derivatives having substituent groups in the benzene rings, naphthalimide trihalomethanesulfonate and its derivatives having substituent groups in the benzene rings.

The substituent groups of these compounds may be aliphatic and aromatic hydrocarbon groups which may have substituent groups.

Combinations of a photoradical generating agent and an oxidizing agent are particularly preferably combinations of a trichlorotriazine type one as the photoradical generating agent and a peroxide as the oxidizing agent.

In order to improve generation of halogen radicals by photoexcitation of a coloring agent, coumarin type, cyanine type, merocyanine type soluble coloring agents may be added. Addition of the soluble coloring agent improves the photosensitivity of the polysilane.

(Silicone Compound)

As a silicone compounds to be used in the invention, those having the following structural formula;

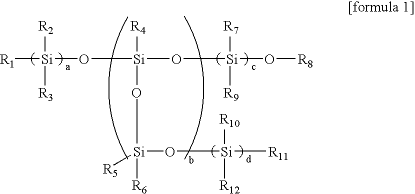

[in the formula, R₁ to R₁₂ separately denote a group selected from aliphatic hydrocarbon groups with 1 to 10 carbons which may be substituted with a halogen or a glycidyloxy group, aromatic hydrocarbon groups with 6 to 12 carbons, and alkoxy groups with 1 to 8 carbons and may be similar or dissimilar to one another; a, b, c, and d separately denote an integer including 0 and satisfy a+b+c+d≧1].

Practical examples of the aliphatic hydrocarbon groups of the silicone compound are straight chain type groups such as methyl, propyl, butyl, hexyl, octyl, decyl, trifluoropropyl, glycidyloxypropyl and the like and alicyclic type groups such as cyclohexyl, methylcyclohexyl and the like. Practical examples of the aromatic hydrocarbon groups are phenyl, p-tolyl, biphenyl and the like. Practical examples of the alkoxy groups are methoxyl, ethoxy, phenoxy, octyloxy, tert-butoxy and the like.

The foregoing types of R₁ to R₁₂ and the values of a, b, c, and d are not particularly important and any may be selected if the silicone compound is compatible with a polysilane and an organic solvent and a film to be obtained is transparent. In consideration of the compatibility, it is preferable to contain hydrocarbon groups same as those which a polysilane to be used have. For example, in the case a polysilane of phenylmethyl type is used, it is preferable to use a silicone compound of a similar phenylmethyl type or diphenyl type. Further, just like those having alkoxy groups with 1 to 8 carbons for at least 2 of R₁ to R₁₂, silicone compounds having two or more alkoxy groups can be used as cross-linking agents. As examples of such silicone compounds, methylphenylmethoxysilicone including alkoxy groups of 15 to 35% by weight, phenylmethoxysilicone and the like can be exemplified.

(Mixing Ratio in Photosensitive Resin Composition)

The mixing ratio in a photosensitive resin composition to be used in the invention is preferably 1 to 30 parts by weight of an oxidizing agent in the case of addition, 1 to 30 parts by weight of a photoradical generating agent in the case of addition, 1 to 200 parts by weight of a silicone compound in the case of addition, and 1 to 20 parts by weight of a soluble coloring agent in the case of addition to 100 parts by weight of a polysilane. The organic solvent is preferable to be in a concentration of 20 to 99% by weight in the entire composition.

(Application Method of Photosensitive Resin Composition)

A coating method of the photosensitive resin composition is not particularly limited and a photosensitive layer can be formed by a coating method such as a spin coating method, a dipping method, a casting method, a vacuum deposition method, a LB method (Langmuir-Blodgett method), and the like. Particularly, a spin coating method for coating by spreading a solution of the photosensitive resin composition on a substrate while rotating the substrate at a high speed is preferable to be used.

In the case of forming a photosensitive layer by the spin coating method, as the organic solvent to be used for the photosensitive resin composition are preferably used aromatic hydrocarbons such as benzene, toluene, and xylene and ether type solvents such as tetrahydrofuran and dibutyl ether. The use amount of the organic solvent is preferably adjusted to keep the concentration of the solid matter in a range of 1 to 50% by weight, that is, the content of the organic solvent is kept preferably in a range of 50 to 99% by weight.

The thickness of the photosensitive layer to be formed on the substrate is preferably 0.01 to 1,000 μm, further preferably 0.1 to 50 μm.

(Exposure of Photosensitive Layer)

UV rays are preferable to be irradiated to the photosensitive layer. As a light source of UV rays, light sources with continuous spectra such as a hydrogen discharge tube, a rare gas discharge tube, a tungsten lamp, a halogen lamp and the like and light sources with discontinuous spectra such as various type laser, a mercury lamp and the like can be employed. As the laser, He—Cd laser, Ar laser, YAG laser, excimer laser and the like can be employed. As the light source, among them is preferable a mercury lamp since it is economical and easy to handle.

UV rays are preferable to be UV rays with wavelength in a range of 250 to 400 nm, which is a σ-σ* absorption region of the polysilane. The irradiation dose is preferably 0.1 to 10 J/cm², further preferably 0.1 to 1 J/cm², per 1 μm thickness of the photosensitive layer.

<Substrate>

The substrate in the invention is not particularly limited but a variety of substrates may be used depending on the uses. For example, insulating substrates such as quartz glass, ceramics and the like; semiconductor substrates of silicon and the like; conductive substrate of aluminum and the like can be used.

<Metal Colloid-Containing Solution>

The production method of a metal colloid-containing solution in the invention is for increasing the concentration of solid matter by removing a portion of a polymer pigment dispersant from a solution containing metal colloidal particles and the polymer pigment dispersant.

The solution containing the metal colloidal particles and the polymer pigment dispersant can be obtained by reducing a metal compound in the presence of the polymer figment dispersant.

The metal compound is for supplying metal colloidal particles by dissolution in a solvent to form metal ion and reduction of the metal ion. The metal to be the metal colloidal particles is not particularly limited, however in terms of formation of excellent conductive coatings and metallic coatings, noble metals or copper is preferable. The noble metals are not particularly limited and include, for example, gold, silver, ruthenium, rhodium, palladium, osmium, iridium, platinum and the like. Among them are preferable gold, silver, platinum, and palladium.

The metal compound is not particularly limited if it contains the foregoing metals and for example, tetrachloroauric acid(III) tetrahydrate (chloroauric acid), silver nitrate, silver acetate, silver(IV) perchlorate, hexachloroplatinic acid(IV) hexahydrate (chloroplatinic acid), potassium chloroplatinic acid, copper(II) chloride dihydrate, copper(II) acetate monohydrate, copper(II) sulfate, palladium(II) chloride dihydrate, rhodium(III) trichloride trihydrate and the like. They may be used solely or in combination of two or more of them.

The metal compound is used so as to adjust the concentration of the metal by mole in the solvent preferably to be 0.01 mol/l or higher. If the concentration is less than 0.01 mol/l, the concentration of the metal by mole in the metal colloid solution to be obtained is too low to be effective. The concentration is preferably 0.05 mol/l or higher, more preferably 0.1 mol/l or higher.

The solvent is not particularly limited if it can dissolve the foregoing metal compound therein and for example, water, organic solvents and the like can be exemplified. The organic solvents are not particularly limited and include, for example, alcohols with 1 to 4 carbons such as ethanol, ethylene glycol and the like; ketones such as acetone; esters such as ethyl acetate and the like. One or more of the foregoing solvents can be used. In the case the solvent is a mixture of water and an organic solvent, as the solvent are preferable water-soluble ones and acetone, methanol, ethanol, ethylene glycol and the like can be exemplified. In the invention, in terms of suitability for a method involving removing a portion of the polymer pigment dispersant by ultrafiltration or the like in a step thereafter, water, an alcohol and a mixed solution of water and an alcohol are preferable.

The polymer pigment dispersant is an amphiphilic copolymer obtained by introducing functional groups with high affinity to the pigment surface into a polymer with a high molecular weight and having a structure including a solvation part and generally used as a pigment dispersant for production of a pigment paste.

The polymer pigment dispersant coexists with metal colloidal particles and is supposed to stabilize the dispersion of metal colloidal particles in the solvent.

The number average molecular weight of the polymer pigment dispersant is preferably 1,000 to 1,000,000. If it is less than 1,000, the dispersion stabilization function is insufficient in some cases and if it exceeds 1,000,000, the viscosity is so high to make handling difficult in some cases. It is further preferably 2,000 to 500,000 and furthermore preferably 4,000 to 500,000.

The polymer pigment dispersant is not particularly limited if it has the above-mentioned properties and examples are those exemplified in Japanese Patent Publication Laid-Open No. H11-80647.

A variety of polymer pigment dispersants can be used as the polymer pigment dispersant and commercialized ones are also usable. The commercialized products are, for example, Solsperse 20000, Solsperse 24000, Solsperse 26000, Solsperse 27000, Solsperse 28000, and Solsperse 41090 (the foregoing are produced by Avecia), Disperbyk 160, Disperbyk 161, Disperbyk 162, Disperbyk 163, Disperbyk 166, Disperbyk 170, Disperbyk 180, Disperbyk 181, Disperbyk 182, Disperbyk 183, Disperbyk 184, Disperbyk 190, Disperbyk 191, Disperbyk 192, Disperbyk 2000, and Disperbyk 2001 (the foregoing are produced by BYK Chem. Co.), Polymer-100, Polymer-120, Polymer-150, Polymer-400, Polymer-401, Polymer-402, Polymer-403, Polymer-450, Polymer-451, Polymer-452, Polymer-453, EFKA-46, EFKA-47, EFKA-48, EFKA-49, EFKA-1501, EFKA-1502, EFKA-4540, and EFKA-4550 (the foregoing are produced by EFKA Chemical Co.), Flowlen DOPA-158, Flowlen DOPA-22, Flowlen DOPA-17, Flowlen G-700, Flowlen TG-720W, Flowlen-730W, Flowlen-740W, and Flowlen-745W (the foregoing are produced by Kyoeisha Chemical Co., Ltd.), Ajisper PA111, Ajisper PB711, Ajisper PB811, Ajisper PB821, and Ajisper PW911 (the foregoing are produced by Ajinomoto Co., Inc.), Jhoncryl 678, Jhoncryl 679, and Jhoncryl 62 (the forgoing are produced by Johnson Polymer Co.). They may be used solely or in combination of two or more of them.

The use amount of the polymer pigment dispersant is preferably 15% by weight or higher in the total amount of the metal of the foregoing metal compound and the polymer pigment dispersant. If it is less than 15% by weight, dispersion stability is possibly degraded at the time of reduction. The upper limit is not particularly defined, however it may be not more than, for example, 10 times as much as the weight of metal in the metal compound.

The metal compound can be reduced to a metal by using a reducing compound in the presence of the foregoing polymer pigment dispersant. The reducing compound is preferably an amine and the metal ion can be reduced to a metal about a normal temperature by stirring and mixing an amine with a solution containing the metal compound and the polymer pigment dispersant. Use of an amine can reduce the metal compound at a reaction temperature of about 5 to 100° C., preferably 20 to 80° C., without requiring a hazardous or harmful reducing agent to be used or heating or special light irradiating apparatus to be employed.

The amine is not particularly limited and, for example, those exemplified in Japanese Patent Publication Laid-Open No. H11-80647 can be employed and examples of the amine are aliphatic amines such as propylamine, butylamine, hexylamine, diethylamine, dipropylamine, dimethylethylamine, diethylmethylamine, triethylamine, ethylenediamine, N,N,N′,N′-tetramethylethylenediamine, 1,3-diaminopropane, N,N,N′,N′-tetramethyl-1,3-diaminopropane, triethylenetetramine, and tetraethylenepantamine; alicyclic amines such as piperidine, N-methylpiperidine, piperazine, N,N′-dimethylpiperazine, pyrrolidine, N-methylpyrrolidine, and morpholine; aromatic amines such as aniline, N-methylaniline, N,N-dimethylaniline, toluidine, anisidine, and phenetidine; and aralkylamines such as benzylamine, N-methylbenzylamine, N,N-dimethylbenzylamine, phenethylamine, xylylenediamine, and N,N,N′,N′-tetramethylxylylenediamine. Also are included, as the amine, alkanolamines such as methylaminoethanol, dimethylaminoethanol, triethanolamine, ethanolamine, diethanolamine, methyldiethanolamine, propanolamine, 2-(3-aminopropylamino)ethanol, butanolamine, hexanolamine, and dimethylaminopropanol. Alkanolamines are preferable and dimethylethanolamine is particularly preferable among them.

Other than the amine, conventionally used reducing agents, for example, alkali metal boron hydride such as sodium boron hydride; hydrazine compounds; citric acid; tartaric acid; ascorbic acid; formic acid; formaldehyde; dithionite and sulfoxylate derivatives and the like. In terms of easy availability, citric acid, tartaric acid, and ascorbic acid are preferable. They may be used solely or in combination of one another and in the case of combination of an amine with citric acid, tartaric acid, or ascorbic acid, citric acid, tartaric acid, or ascorbic acid is preferably used in form of its salt. Further, citric acid and the sulfoxylate derivatives can be improved in the reducing capability by use in combination with iron(II) ion.

The addition amount of the foregoing reducing agents is preferably not less than an amount needed to reduce the metal in the foregoing metal compound. If it is less than the needed amount, reduction is possibly insufficient. The upper limit of the amount is not particularly defined, however it may be preferably not more than 30 times, more preferably not more than 10 times, as much as the amount needed to reduce the metal in the foregoing metal compound.

Other than the chemical reduction method by adding these reducing compounds, a method for irradiation using a high pressure mercury lamp can be employed.

A method for adding the foregoing reducing compound is not particularly limited and, for example, the compounds may be added after the foregoing polymer pigment dispersant and in such a case, for example, reduction can be promoted by at first dissolving the foregoing polymer pigment dispersant in a solvent and further dissolving one of the reducing compound and the metal compound and then adding the other to the obtained solution. The method for adding the foregoing reducing compound may be carried out by at first mixing the polymer pigment dispersant and the foregoing reducing compound and adding the mixture to a solution of the metal compound.

The foregoing reduction gives a solution containing metal colloidal particles with an average particle diameter of about 5 nm to 100 nm.

The method for bringing the photosensitive layer on the substrate into contact with the metal colloid-containing solution is preferably a method for dipping the photosensitive layer together with the substrate in the metal colloid-containing solution. Although the dipping time is not particularly limited, for example, dipping may be for about 1 second to 10 minutes. After dipping, the photosensitive layer is dried generally at 10° C. to 500° C. in normal pressure or reduced pressure.

As described, since silanol groups are formed to be hydrophilic in the exposed parts where a latent image is formed, the metal colloid is adsorbed in the parts. Incidentally, to promote adsorption of metal colloid, at the time of bringing the metal colloid-containing solution into contact with the photosensitive layer, heating temperature may be at 40 to 200° C.

Hereinafter, the invention will be described more particularly with reference to Examples, however it is not intended that the invention be limited to the following Examples and modifications and substitutions can be made without departing from the spirit and scope of the present invention.

### PREPARATION EXAMPLE 1

### Preparation of Polysilane

A flask of 1,000 ml volume equipped with a stirring apparatus was loaded with toluene 400 ml and 13.3 g of sodium. The contents in the flask were heated to 111° C. in a yellow room where UV rays were shut out and stirred at a high speed to finely disperse sodium in toluene. Further, 42.1 g of phenylmethyldichlorosilane and 4.1 of tetrachlorosilane were added and stirred for 3 hours to carry out polymerization. After that, ethanol was added to the obtained reaction mixture to inactivate excess sodium. After washing with water, the separated organic layer was poured in ethanol to precipitate a polysilane. The obtained low grade polysilane was repeatedly precipitated in ethanol three times to obtain network type polymethylphenylsilane with a weight average molecular weight of 11,600.

### PREPARATION EXAMPLE 2

### Preparation of Silver Colloid-Containing Solution

A flask of 2 l volume was loaded with 119.1 g of Disperbyk 190 (produced by Byk Chem. Co.), 294.3 g of 1 mol/l nitric acid, and 294.3 g of ion exchanged water. The flask was put in a water bath and the contents were stirred at 50° C. until Disperbyk 190 was dissolved. To the flask was added 50.0 g of silver nitrate dissolved in 883.0 g of ion exchanged water under stirring and stirred at 70° C. for 10 minutes. Next, when 131.0 g of dimethylaminoethanol was added, the solution was turned to black at once and the solution temperature was increased to 76° C. After being kept still and when cooled to 70° C., the solution was continuously stirred at the temperature for 2 hours to obtain an aqueous solution of silver colloid with blackish yellow. The resulting reaction solution was transferred to a 1 l polymer bottle and kept still in a thermostat vessel at 60° C. for 18 hours. Next, an ultrafiltration module AHP1010 (manufactured by Asahi Chemical Industry Co., Ltd.; fractional molecular weight 50,000; no. of membranes used: 400), a magnet pump, and a 3 l stainless cup having a tube connection port in a lower part were connected with silicon tubes to assemble an ultrafiltration apparatus. After the foregoing reaction solution kept still in a thermostat vessel at 60° C. for 18 hours was transferred to the stainless cup and further 2 l of ion exchanged water was added, ultrafiltration was carried out by operating the pump. After about 40 minutes, when the amount of the filtrate from the module reached 2 l, 2 l of ion exchanged water was added to the stainless cup. Next, that the conductivity of the filtrate was decreased to be 300 μS/cm was confirmed, and the mother solution was concentrated to be 500 ml in volume.

Successively, an ultrafiltration apparatus comprising a 500 ml stainless cup to contain the mother solution, ultrafiltration module AHP0013 (manufactured by Asahi Chemical Industry Co., Ltd.; fractional molecular weight 50,000; no. of membranes used: 100), a tube pump, and an aspirator was assembled. The obtained mother solution was loaded in the stainless cup and subjected to concentration to increase the solid matter concentration. When the mother solution was concentrated to be about 100 ml in volume, the pump was stopped and the concentration was finished to obtain an aqueous silver colloid solution with 30% of solid matter. The average particle diameter of the silver colloidal particles in the solution was 27 nm.

### PREPARATION EXAMPLE 3

### Preparation of Gold Colloid-Containing Solution

A flask of 2 l volume was loaded with 21.5 g of Disperbyk 191 (produced by Byk Chem. Co.) and 280.2 g of ethanol. The flask was put in a water bath and the contents were stirred at 50° C. until Disperbyk 191 was dissolved. To the flask was added 30.0 g of chloroauric acid dissolved in 280.2 g of ethanol under stirring and stirred at 50° C. for 10 minutes. Next, when 32.4 g of dimethylaminoethanol was added, the solution was turned to black at once and the solution temperature was increased to 63° C. After being kept still and when cooled to 50° C., the solution was continuously stirred at the temperature for 2 hours to obtain an ethanol solution of gold colloid with blackish purple.

Next, an ultrafiltration module AHP1010 (manufactured by Asahi Chemical Industry Co., Ltd.; fractional molecular weight 50,000; no. of membranes used: 400), a magnet pump, and a 3 l stainless cup having a tube connection port in a lower part were connected with silicon tubes to assemble an ultrafiltration apparatus. After the foregoing ethanol solution of gold colloid was transferred to the stainless cup and further 2 l of ion exchanged water was added, ultrafiltration was carried out by operating the pump. After about 40 minutes, when the amount of the filtrate from the module reached 2 l, 2 l of ion exchanged water was added to the stainless cup. Next, that the conductivity of the filtrate was decreased to be 30 μS/cm was confirmed, and the mother solution was concentrated to be 500 ml in volume.

Successively, an ultrafiltration apparatus comprising a 500 ml stainless cup to contain the mother solution, ultrafiltration module AHP0013 (manufactured by Asahi Chemical Industry Co., Ltd.; fractional molecular weight 50,000; no. of membranes used: 100), a tube pump, and an aspirator was assembled. The obtained mother solution was loaded in the stainless cup and subjected to concentration to increase the solid matter concentration. When the mother solution was concentrated to be about 100 ml in volume, the pump was stopped and the concentration was finished to obtain an aqueous gold colloid solution with 30% of solid matter. The average particle diameter of the silver colloidal particles in the solution was 21 nm.

### EXAMPLE 1

The network type polysilane 100 parts by weight obtained in the Preparation example 1, BTTB (3,3′,4,4′-tetra-(tert-butylperoxycarbonyl)benzophenone, produced by Nippon Oil & Fats Co., Ltd.) as an oxidizing agent 15 parts by weight, and TSR 165 (methylphenylmethoxysilicone, produced by GE Toshiba Silicone Co., Ltd.) as a silicone compound 50 parts by weight were dissolved in toluene 1,215 parts by weight to obtain a photosensitive resin composition. The photosensitive resin composition was applied in a thickness of 2 μm to a glass substrate by using a spin coater and dried at 120° C. for 10 minutes in an oven to form a photosensitive layer.

Next, a photomask was put on the photosensitive layer and UV rays with 365 nm wavelength and dose of 2,000 mJ/cm² were radiated by employing a 500 W ultrahigh pressure xenon mercury lamp to expose the photosensitive layer in prescribed patterns and form exposed parts.

Next, the resulting photosensitive layer together with the substrate was immersed in the silver colloid-containing solution obtained by the Preparation Example 2 for 10 minutes and after the immersion, the photosensitive layer was washed with deionized water and dried by air blow to adsorb silver colloid in the exposed parts. After that, drying was carried out for 30 minutes in a drying furnace heated at 200° C.

It was confirmed that yellow patterns were formed in the obtained film and the film was smooth and excellent in film quality. When the film was rubbed by a wiping cloth, no dropping off of the film was observed to find the film keeping sufficiently high adhesion strength.

Even after heating at 350° C., no cracking and peeling and discoloration of the film took place and film condition was kept as it was before heating.

### EXAMPLE 2

The network type polysilane 100 parts by weight obtained in the Preparation example 1, BTTB (3,3′,4,4′-tetra-(tert-butylperoxycarbonyl)benzophenone, produced by Nippon Oil & Fats Co., Ltd.) as an oxidizing agent 15 parts by weight, TAZ-110 (2,4-bis(trichloromethyl)-6-(p-methoxyphenylvinyl)-1,3,5-triazine, produced by Midori Kagaku Co., Ltd.) as a photoradical generating agent 10 parts by weight, and TSR 165 (methylphenylmethoxysilicone, produced by GE Toshiba Silicone Co., Ltd.) as a silicone compound 50 parts by weight were dissolved in toluene 1,215 parts by weight to obtain a photosensitive resin composition. The photosensitive resin composition was applied in a thickness of 2 μm to a glass substrate by using a spin coater and dried at 120° C. for 10 minutes in an oven to form a photosensitive layer.

Next, a photomask was put on the photosensitive layer and UV rays with 365 nm wavelength and dose of 1,500 mJ/cm² were radiated by employing a 500 W ultrahigh pressure xenon mercury lamp to expose the photosensitive layer in prescribed patterns and form exposed parts.

Next, the resulting photosensitive layer together with the substrate was immersed in the gold colloid-containing solution obtained by the Preparation Example 3 for 5 minutes and after the immersion, the photosensitive layer was washed with deionized water and dried by air blow to adsorb gold colloid in the exposed parts. After that, drying was carried out for 30 minutes in a drying furnace heated at 200° C.

It was confirmed that red purple patterns were formed in the obtained film and the film was smooth and excellent in film quality. When the film was rubbed by a wiping cloth, no dropping off of the film was observed to find the film keeping sufficiently high adhesion strength.

Even after heating at 350° C., no cracking and peeling and discoloration of the film took place and film condition was kept as it was before heating.

### EXAMPLE 3

The polysilane thin film in which silver colloid patterns were formed and obtained by Example 1 was immersed in an electroless copper plating solution (trade name: OPC-700 electroless plating M, produced by Okuno Chemical Industries Co., Ltd.) for 20 minutes and then washed with water and dried (at 100° C. for 10 minutes) to precipitate copper with a thickness of 1 μm only on the patterns of the silver colloid.

The obtained film was found having copper color patterns and high light shutting and shielding properties, smooth, and excellent in film quality.

When the film was rubbed by a wiping cloth, no dropping off of the film was observed to find the film keeping sufficiently high adhesion strength.

Using the substrate bearing the film as a photomask, a photosensitive layer was newly formed from the photosensitive resin composition obtained in Example 1 by the method described in the Example 1 and UV rays with 365 nm wavelength and dose of 1,500 mJ/cm² were radiated by employing a 500 W ultrahigh pressure xenon mercury lamp to expose the photosensitive layer in prescribed patterns and form exposed parts.

Next, the resulting photosensitive layer together with the substrate was immersed in the silver colloid-containing solution obtained by the Preparation Example 2 for 10 minutes and after the immersion, the photosensitive layer was washed with deionized water and dried by air blow to adsorb silver colloid in the exposed parts.

It was confirmed that yellow patterns were formed in the obtained film and the film was smooth and excellent in film quality. When the film was rubbed by a wiping cloth, no dropping off of the film was observed to find the film keeping sufficiently high adhesion strength.

Accordingly, the film obtained by this Example was found effective as a light shielding film of a photomask and useful as not only a conductive film but also a light shielding film for methods for forming metal patterns in a wide range of uses.

### PREPARATION EXAMPLE 4

A red purple dyeing solution was prepared by mixing Astra Phloxine FF (basic dye; produced by Hodogaya Chemical Co., Ltd.) 1.4 g, Victoria Blue BH (basic dye; produced by Hodogaya Chemical Co., Ltd.) 0.6 g, ion exchanged water 178 g, and acetonitrile 20 g.

### PREPARATION EXAMPLE 5

A 1,000 cc beaker was loaded with tetraethoxysilane 168 g, methyltriethoxysilane 84 g, ion exchanged water 250 g, and ethanol 96 g and while the contents being stirred by a magnetic stirrer, 35% concentration hydrochloric acid 1.92 g was added. While the temperature of the solution being kept at 20° C., stirring was continued for 15 minutes to obtain a transparent and uniform silica sol. A 300 cc beaker was loaded with the silica sol 56 g, ion exchanged water 139 g and Red AQ-866 (nonionic pigment paste; produced by Mikuni Color Works Ltd.) 35 g, and Blue AQ-010 (nonionic pigment paste; produced by Mikuni Color Works Ltd.) 15 g and after the contents was stirred for 30 minutes, ethanol 40 g was added to produce a red purple color sol.

### COMPARATIVE EXAMPLE 1

After the photosensitive layer formation and exposure were carried out in the same manner as Example 1, the photosensitive layer together with the substrate was immersed in the dye solution for 10 minutes obtained in the Preparation example 4 and after the immersion, the photosensitive layer was washed with deionized water and dried by air blow to adsorb the dye in the exposed parts. After that, drying was carried out for 30 minutes in a drying furnace heated at 200° C.

It was confirmed that red purple patterns were formed in the obtained film and the film was smooth and excellent in film quality. When the film was rubbed by a wiping cloth, no dropping off of the film was observed to find the film keeping sufficiently high adhesion strength.

However, when the film being heated at 350° C., the dye was thermally decomposed and turned to be brownish without maintaining the red purple color.

### COMPARATIVE EXAMPLE 2

After the photosensitive layer formation and exposure were carried out in the same manner as Example 1, the photosensitive layer together with the substrate was immersed in the color sol solution for 10 minutes obtained in the Preparation example 5 and after the immersion, the photosensitive layer was washed with deionized water and dried by air blow to adsorb the dye in the exposed parts. After that, drying was carried out for 30 minutes in a drying furnace heated at 200° C.

It was confirmed that red purple patterns were formed in the obtained film and the film was smooth and excellent in film quality. When the film was rubbed by a wiping cloth, no dropping off of the film was observed to find the film keeping sufficiently high adhesion strength.

However, when the film being heated at 350° C., the dye was thermally decomposed and turned to be brownish without maintaining the red purple color.

According to the invention, metal colloid patterns excellent in heat resistance can be formed with high adhesion strength by simple steps. The metal colloid patterns formed by the invention can be used for forming metal patterns in a wide range of uses in color filters for various types of displays and catalysts for metal plating and in electric, electronic, and communication fields.

What is claimed is:

1. A metal colloid pattern formation method for forming metal colloid patterns on a substrate, wherein the method involves steps of forming a photosensitive layer on a substrate by applying a photosensitive resin composition containing an organic solvent and a polysilane soluble in the organic solvent to the substrate, forming a latent image of the patterns by selectively exposing the photosensitive layer, bringing a metal colloid-containing solution into contact with the photosensitive layer, and forming patterns of the metal colloid by adsorbing the metal colloid in the exposed parts.

2. The metal colloid pattern formation method according to claim 1, wherein the photosensitive resin composition further contains an oxidizing agent, a photoradical generating agent, or a silicone compound.

3. The metal colloid pattern formation method according to claim 1, wherein the metal colloid-containing solution contains a metal colloid and a polymer pigment dispersant.

4. The metal colloid pattern formation method according to claim 2, wherein the metal colloid-containing solution contains a metal colloid and a polymer pigment dispersant.
